(19) United States
(12) Patent Application Publication
(10) Pub. No.: US 2012/0119815 A1
(43) Pub. Date: May 17, 2012

(54) SWITCHING CIRCUIT OF SEMICONDUCTOR APPARATUS

(75) Inventor: Won Beom Choi, Icheon-si (KR)

(73) Assignee: HYNIX SEMICONDUCTOR INC., Icheon-si (KR)

(21) Appl. No.: 13/217,402

(22) Filed: Aug. 25, 2011

(30) Foreign Application Priority Data
Nov. 15, 2010 (KR) 10-2010-0113290

(51) Int. Cl. H03K 17/00

(52) U.S. Cl. 327/407

(57) ABSTRACT

A switching circuit of a semiconductor apparatus includes a first switching unit configured to substantially prevent a leakage current applied from an outside and simultaneously switch a first signal with a first high voltage bias level, and a second switching unit configured to switch a second signal with a second high voltage bias according to the first high voltage bias level. The first switching unit and the second switching unit are selectively switched by a first enable signal and a second enable signal, which are applied from an outside, to generate a global bias signal.

### CROSS-REFERENCES TO RELATED APPLICATION

The present application claims priority under 35 U.S.C. §119(a) to Korean application No. 10-2010-0113290, filed on Nov. 15, 2010, in the Korean Intellectual Property Office, which is incorporated herein by reference in its entirety.

### BACKGROUND

1. Technical Field

The present invention relates generally to a semiconductor circuit, and more particularly, to a switching circuit of a semiconductor apparatus.

2. Related Art

Many and various configurations of internal circuits in a semiconductor apparatus are operated utilizing various high voltage biases. A switching circuit is provided in a semiconductor apparatus to selectively control the various high voltage biases needed for the internal circuit operations.

More specifically, the switching circuit includes a plurality of switching units that are electrically connected to each other. The plurality of switching units are constructed to correspond with the various internal circuit configurations in a one-to-one relationship, and the various internal circuit configurations are driven with high voltage bias levels that are different from each other.

The plurality of switching units, however, are limited by a breakdown voltage when the switching units attempts to control high voltage biases with voltage levels not less than the external power supply voltage levels, and this imposes a limitation in the highest bias level usable as a switch.

That is, when a first switching unit outputting the highest bias among the plurality of switching units is not selected, but a second switching unit outputting a high voltage bias with bias level lower than the highest bias level is selected, the second switching unit will output the bias voltage as a global bias signal. The global bias signal is inputted to a corresponding internal element, and simultaneously the first switching unit is turned on by a current introduced from the second switching unit outputting the high voltage bias, causing a short-circuit with the highest bias VPP. As a result, breakdown of an element is caused, resulting in the reduction in the reliability of the element.

### SUMMARY

A switching circuit of a semiconductor apparatus capable of improving a driving speed of an internal circuit is described herein.

In an embodiment of the present invention, a switching circuit of a semiconductor apparatus includes: a first switching unit configured to substantially prevent a leakage current applied from outside and simultaneously switch a first signal with a first high voltage bias level; and a second switching unit configured to switch a second signal with a second high voltage bias according to the first high voltage bias level, wherein the first switching unit and the second switching unit are selectively switched by a first enable signal and a second enable signal, which are applied from outside, to generate a global bias signal.

In another embodiment of the present invention, a switching circuit of a semiconductor apparatus includes: a first switching unit configured to generate a first signal with a first high voltage bias level by a first highest voltage bias in response to a first enable signal, and simultaneously determine output of the first enable signal; and a second switching unit configured to generate a second signal with a second high voltage bias level by a second highest voltage bias in response to a second enable signal.

Further, in another embodiment of the present invention, a switching circuit of a semiconductor apparatus includes: a plurality of switching units configured to selectively switch signals with different high voltage bias levels according to an enable signal applied from outside, and wherein, among the plurality of switching units, one switching unit generating the signal by a highest voltage bias level includes: a blocking section configured to substantially prevent a leakage current introduced from other switching units.

### BRIEF DESCRIPTION OF THE DRAWINGS

Features, aspects, and embodiments are described in conjunction with the attached drawings, in which:

FIG. 1 is a block diagram illustrating a switching circuit of a semiconductor apparatus according to an embodiment of the invention;

FIG. 2 is a detailed circuit diagram of the first switching unit illustrated in FIG. 1; and

FIG. 3 is a detailed circuit diagram of the second switching unit illustrated in FIG. 1.

### DETAILED DESCRIPTION

Hereinafter, a switching circuit of a semiconductor apparatus according to the present invention will be described in detail with reference to the accompanying drawings through exemplary embodiments.

FIG. 1 is a block diagram illustrating a switching circuit 100 of a semiconductor apparatus according to an embodiment of the invention.

Referring to FIG. 1, a switching circuit 100 of a semiconductor apparatus according to an embodiment of the invention includes a first switching unit 120 and a second switching unit 140.

The first switching unit 120 is configured to substantially prevent a leakage current applied from outside and also generate (which may occur simultaneously) a first signal HV1_out, which has a first high voltage bias level by the first highest voltage bias VPP, as a global bias signal Global Bias. The first highest voltage bias VPP refers to the highest bias level available in a chip and, although not discussed in detail, refers to a bias level generated by pumping an external driving voltage that is externally provided by a level pumping circuit.

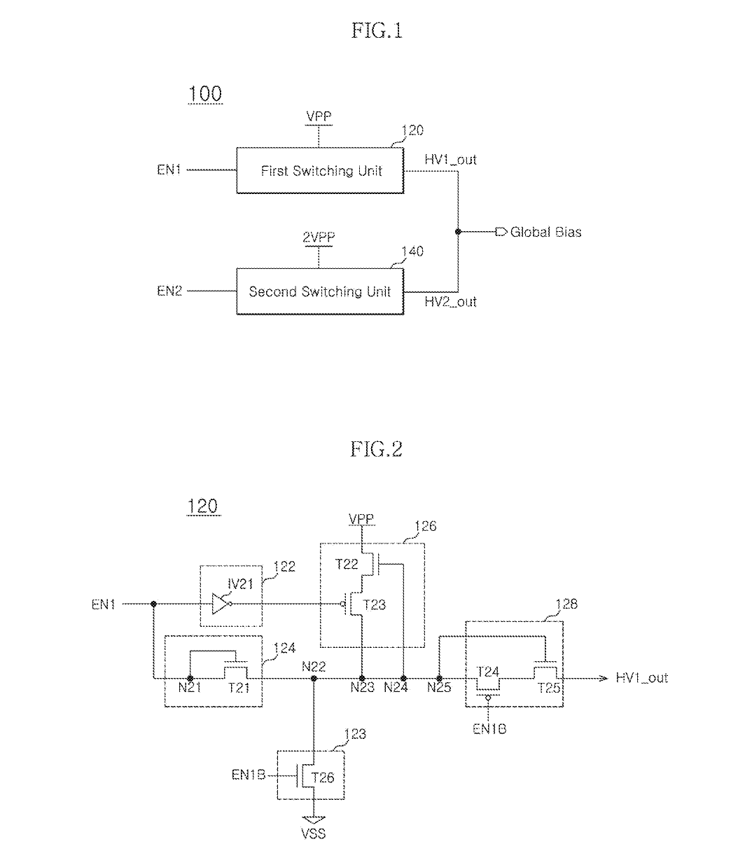

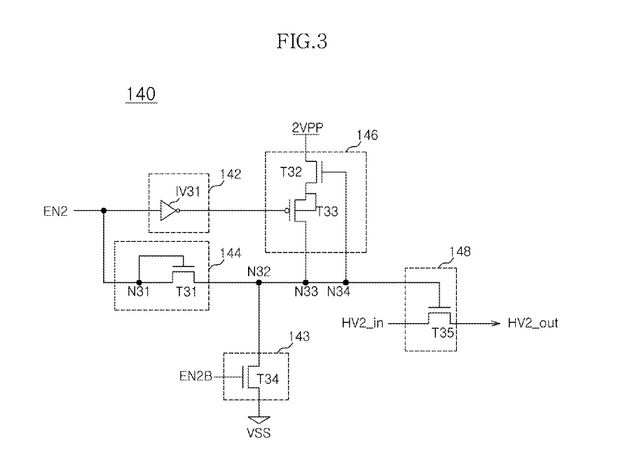

A blocking section 128, now referring to FIG. 2, is provided at the output terminal of the first switching unit 120 for substantially preventing a leakage current that may be applied from the second switching unit 140, thereby substantially preventing the leakage current that would cause a short-circuit between the first highest voltage bias VPP and the first high voltage bias. The first and second switching units 120, 140 according to an embodiment of the invention will be described in more detail with reference to FIGS. 2-3 respectively.

The second switching unit 140 is configured to receive a second highest voltage bias 2 VPP substantially equal to the first high voltage bias level of the first signal HV1_out outputted from the first switching unit 120, and output a second signal HV2_out, which has a second high voltage bias level by the second highest voltage bias 2 VPP, as the global bias signal Global Bias.

The first switching unit 120 and the second switching unit 140 may be selectively switched by a first enable signal EN1 and a second enable signal EN2 that are applied externally. The first and second enable signals EN1, EN2 are signals that can be used to operate one among many internal elements in the semiconductor apparatus, and they may serve as the element selection signals for activating a corresponding element.

The switching circuit 100 of the semiconductor apparatus according to an embodiment of the invention includes the blocking section 128 that can prevent destruction of an element due to a leakage current applied to the first switching unit 120 from the second switching unit 140, and this allows the driving speed of the semiconductor apparatus to increase.

Furthermore, the switching circuit 100 of the semiconductor apparatus according to an embodiment of the invention provides the highest bias level to be available in a chip and improves the breakdown resistance characteristics of a transistor with no influence on the chip size increase.

FIG. 2 is a detailed circuit diagram of the first switching unit 120 shown in FIG. 1.

Referring to FIG. 2, the first switching unit 120 according to an embodiment of the invention includes a first bias providing section 126, a blocking section 128, a first output section 124, and a first current adjustment section 123.

The first bias providing section 126 is configured to provide the first highest voltage bias VPP according to an inverted level of the first enable signal EN1.

The first bias providing section 126 includes a twenty-third transistor T23 and a twenty-second transistor T22. The twenty-third transistor T23 is configured to be activated to provide the first highest voltage bias VPP to a twenty-third node N23 according to the inverted level of the first enable signal EN1, which is inverted by an inverter IV21 of a first inversion section 122. The twenty-second transistor T22 is configured to be activated according to a level value detected at a twenty-fourth node N24, wherein the nodes N23 and N24 as well as the node 25 are common nodes as shown in FIG. 2.

The blocking section 128 is configured to output the first signal HV1_out having the first high voltage bias level, which is based on the first highest voltage bias VPP provided by the first bias providing section 126, as the global bias signal Global Bias, and also substantially prevent introduction of a leakage current emanating from the second signal HV2_out outputted by the second switching unit 140.

The blocking section 128 includes a first selection part T24 and a second selection part T25. The first selection part T24 is configured to be activated according to the inverted level of the first enable signal EN1. The second selection part T25 is configured to be activated by detecting the level of the first highest voltage bias VPP through a twenty-fifth node N25 formed at an input terminal of the first selection part T24. The first selection part T24, for example, may be a PMOS transistor, and the second selection part T25, for example, may be an NMOS transistor.

The first output section 124 is configured to be activated in response to a value detected at a twenty-first node N21, that is, the level of the first enable signal EN1, and the first output section 124, for example, may be an NMOS transistor T21 coupled in a diode configuration.

The first current adjustment section 123 is configured to adjust the amount of current flowing through a twenty-second node N22 formed between the first output section 124 and the blocking section 128 in response to the inverted level of the first enable signal EN1, and the first current adjustment section 123, for example, may be an NMOS transistor T26.

For example, in operating the first switching unit 120 according to an embodiment of the invention, when the first enable signal EN1 is inputted at a high level from outside, the first output section 124 is activated and the current level flowing through the twenty-second node N22 is increased.

Further, the high level first enable signal EN1 is inverted by the first inversion section 122 to have a low level and is then inputted to the first bias providing section 126. The high level first enable signal EN1 is inputted to the gate of the twenty-third transistor T23 to activate the twenty-third transistor T23. Then, the twenty second transistor T23 turns on by the high level value of the twenty-fourth node N24 inputted to the gate of the twenty-second transistor T22. The high level value is maintained at the twenty-fourth node by the first output section 124. In this manner, the first bias providing section 126 provides the first highest voltage bias VPP available in a chip.

The first current adjustment section 123 receives a signal EN1B, which is the inverted first enable signal EN1, so that the level of the twenty-second node N22 may be substantially maintained.

In addition, the first selection part T24 of the blocking section 128 is configured to be activated by receiving the signal EN1B, which is the inverted first enable signal EN1, and to output a detection signal detected at the twenty-fifth node N25 to the second selection part T25.

The second selection part T25 is configured to receive the high level value of the twenty-fifth node N25 through its gate and output the first signal HV1_out with a high level, which is detected at the twenty-fifth node N25.

On the other hand, when the first enable signal EN1 of low level is inputted, the first output section 124 is deactivated and the amount of a current flowing through the twenty-second node N22 is reduced.

The first enable signal EN1 of low level is inverted by the first inversion section 122 to have a high level, and the high level signal produced by the inversion is then inputted to the first bias providing section 126. The high level signal produced by the inversion of the first enable signal EN1 of low level is inputted to the gate of the twenty-third transistor T23, so that the twenty-third transistor T23 would not operate. Since the twenty-second transistor T22 receiving the value of the twenty-fourth node N24 having a low level value by the first output section 124 through a gate thereof also does not operate, the first bias providing section 126 does not generate the first highest voltage bias VPP.

The first current adjustment section 123 is activated by receiving the signal EN1B, which is the inverted first enable signal EN1, so that the level of the twenty-second node N22 may be changed to a low level.

In addition, the first selection part T24 of the blocking section 128 is deactivated by receiving the signal EN1B, which is the inverted first enable signal EN1, and would not operate. The second selection part T25 receives the detection value of the twenty-fifth node N25 with a low level through a gate thereof and thus would not operate. That is, the blocking section 128 does not allow the first switching unit 120 to operate if the first enable signal EN1 is not activated, thereby substantially preventing a leakage current applied from the second switching unit 140.

FIG. 3 is a detailed circuit diagram of the second switching unit 140 illustrated in FIG. 1.

Referring to FIG. 3, the second switching unit 140 according to an embodiment of the invention includes a second bias providing section 146, a second output section 144, a second current adjustment section 143, and a signal transfer section 148.

The second bias providing section 146 is configured to provide the second highest voltage bias 2 VPP according to the level of the second enable signal EN2. The second highest voltage bias 2 VPP may be substantially equal to the first high voltage bias level which is a high level of the first signal HV1_out of the first switching unit 120. In this regard, the second signal HV2_out may have a second high voltage bias level lower than the second highest voltage bias 2 VPP.

The second bias providing section 146 includes a thirty-third transistor T33 and a thirty-second transistor T32. The thirty-third transistor T33 is configured to be activated to provide the second highest voltage bias 2 VPP to a thirty-third node N33 according to the level of the second enable signal EN2, which is inverted by a second inversion section 142. The thirty-second transistor T32 is configured to be activated according to a level value detected at a thirty-fourth node N34, wherein the thirty-third node N33 and the thirty-fourth node N34 are common nodes.

The second output section 144 is configured to be activated according to a detection value of a thirty-first node N31 to determine the level of a thirty-second node N32, and the second output section 144, for example, may comprise an NMOS transistor T31.

The second current adjustment section 143 is configured to adjust the amount of current flowing through the thirty-second node N32 formed between the second output section 144 and the second bias providing section 146 according to the level of the second enable signal EN2. The second current adjustment section 143, for example, may comprise an NMOS transistor T34 which may be activated according to EN2B, which is the inverted second enable signal EN2.

The signal transfer section 148 is configured to output the second signal HV2_out in response to the level of the second highest voltage bias 2 VPP provided by the second bias providing section 146. The signal transfer section 148 may include an NMOS transistor T35 which may be activated in response to the level of the second highest voltage bias 2 VPP.

For example, in the operation of the second switching unit 140 according to an embodiment of the invention as described above, when the second enable signal EN2 is inputted at a high level from outside, the second output section 144 is activated and the current level flowing through the thirty-second node N32 is increased.

The second enable signal EN2 at the high level is inverted by the second inversion section 142 to have a low level and is then inputted to the second bias providing section 146. The second enable signal EN2 at the low level is inputted to the gate of the thirty-third transistor T33 to activate the thirty-third transistor T33. At this time, since the thirty-second transistor T32 receiving the value of the thirty-fourth node N34 having a high level value by the second output section 144 through its gate is also turned on, the second bias providing section 146 may provide the second highest voltage bias 2 VPP lower than the first highest voltage bias VPP.

The second current adjustment section 143 receives the signal EN2B, which is an inverted second enable signal EN2, so that the level of the thirty-second node N32 may be substantially maintained.

In addition, the signal transfer section 148 is configured to be turned on by receiving the detection value of the thirty-fourth node N34 of high level through its gate, and output the second signal HV2_out as the global bias signal Global Bias.

Meanwhile, when the second enable signal EN2 is inputted at a low level from outside, the second output section 144 is deactivated and the amount of current flowing through the thirty-second node N32 is reduced.

The second enable signal EN2 at the low level is inverted by the second inversion section 142 to have a high level, and is then inputted to the second bias providing section 146. The second enable signal EN2 of high level is inputted to the gate of the thirty-third transistor T33, so that the thirty-third transistor T33 does not operate.

In addition, since the thirty-second transistor T32 receiving the value of the thirty-fourth node N34 having a low level value by the second output section 144 through a gate thereof also does not operate, the second bias providing section 146 may not provide the second highest voltage bias 2 VPP.

The second current adjustment section 143 is activated by receiving a high level signal, which is the signal EN2B with the inverted level of the second enable signal EN2, so that the charge amount of the thirty-second node N32 is reduced.

While certain embodiments have been described above, it will be understood to those skilled in the art that the embodiments described are by way of example only. Accordingly, the switching circuit of the semiconductor apparatus described herein should not be limited based on the described embodiments. Rather, the switching circuit of the semiconductor apparatus described herein should only be limited in light of the claims that follow when taken in conjunction with the above description and accompanying drawings.

What is claimed is:

1. A switching circuit of a semiconductor apparatus, comprising:
a first switching unit configured to substantially prevent introduction of a leakage current and output a first signal having a first high voltage bias level as a global bias signal; and
a second switching unit configured to output a second signal having a second high voltage bias level according to the first high voltage bias level as the global bias signal,
wherein the first switching unit and the second switching unit are selectively switched by a first enable signal and a second enable signal so as to generate the global bias signal from the switched one of the first and second switching units.

2. The switching circuit of the semiconductor apparatus according to claim 1, wherein the first switching unit comprises:
a first bias providing section configured to provide a highest voltage bias according to a level of the first enable signal; and
a blocking section configured to output the first signal as the global bias signal according to the highest voltage bias provided by the bias providing section and substantially prevent introduction of a current from the second signal having the second high voltage bias level.

3. The switching circuit of the semiconductor apparatus according to claim 2, wherein the first switching unit comprises:
a first output section configured to selectively output the first enable signal to the blocking section; and
a first current adjustment section configured to adjust an amount of current flowing through a first node formed between the first output section and the blocking section according to the level of the first enable signal.

4. The switching circuit of the semiconductor apparatus according to claim 3, wherein the blocking section comprises:
a first selection part configured to be turned on according to the level of the first enable signal; and
a second selection part configured to be turned on according to the level of the first node, which is also formed at an input terminal of the first selection part.

5. The switching circuit of the semiconductor apparatus according to claim 4, wherein the first selection part is configured to output the first enable signal to the second selection part when the first enable signal has a low level.

6. The switching circuit of the semiconductor apparatus according to claim 5, wherein the second selection part is configured to output the first enable signal, which is outputted from the first selection part, according to the level of the first node.

7. A switching circuit of a semiconductor apparatus, comprising:
a first switching unit configured to generate a first signal having a first high voltage bias level based on a first highest voltage bias in response to a first enable signal and determine output of the first enable signal; and
a second switching unit configured to generate a second signal having a second high voltage bias level based on a second highest voltage bias in response to a second enable signal.

8. The switching circuit of the semiconductor apparatus according to claim 7, wherein the first switching unit comprises:
a first bias providing section configured to provide the first highest voltage bias according to a level of the first enable signal;
a blocking section configured to output the first signal with the first highest voltage bias level provided by the first bias providing section as a global bias signal, and substantially prevent backflow of the second signal having the second high voltage bias level into the first switching unit;
a first output section configured to be turned on according to the first enable signal; and
a first current adjustment section configured to adjust an amount of current flowing through a first node formed between the first output section and the blocking section according to the level of the first enable signal.

9. The switching circuit of the semiconductor apparatus according to claim 8, wherein the blocking section comprises:
a first selection part configured to be turned on according to the level of the first enable signal; and
a second selection part configured to be turned on according to the first highest voltage bias level through the first node, which is also formed at an input terminal of the first selection part.

10. The switching circuit of the semiconductor apparatus according to claim 9, wherein the first output section is configured to be activated when the first enable signal of high level is inputted so as to increase the amount of the current flowing through the first node.

11. The switching circuit of the semiconductor apparatus according to claim 10, wherein the first selection part is configured to output a signal having a value of the first node to the second selection part when the first enable signal has a low level.

12. The switching circuit of the semiconductor apparatus according to claim 11, wherein the second selection part is configured to output the signal outputted from the first selection part as the global bias signal according to the signal level detected at the first node.

13. The switching circuit of the semiconductor apparatus according to claim 12, wherein the second switching unit comprises:
a second bias providing section configured to provide the second highest voltage bias according to a level of the second enable signal;
a second output section configured to activate a second node according to the second enable signal;
a second current adjustment section configured to adjust an amount of current flowing through the second node formed between the second output section and the second bias providing section according to the level of the second enable signal; and
a signal transfer section configured to output the second signal having a level lower than the second highest voltage bias level in response to the second highest voltage bias provided by the second bias providing section.

14. A switching circuit of a semiconductor apparatus, comprising:
a plurality of switching units configured to selectively switch signals with different high voltage bias levels provided to the switching units according to enable signals provided to the switching units, and
wherein, one of the switching units capable of generating the signal having the highest voltage bias level comprises:
a blocking section configured to substantially prevent a leakage current introduced from other switching units.

15. The switching circuit of the semiconductor apparatus according to claim 14, wherein the switching unit generating the signal having the highest voltage bias level comprises:
a first bias providing section configured to provide a highest voltage bias according to a level of the first enable signal provided to the switching unit capable of generating the signal having the highest voltage bias level;
a blocking section configured to output a first signal having the highest voltage bias level provided by the first bias providing section as a global bias signal, and to substantially prevent introduction of a leakage current from the other switching units;
a first output section configured to be turned on according to the first enable signal; and
a first current adjustment section configured to adjust an amount of current flowing through a first node formed between the first output section and the blocking section according to the level of the first enable signal.

16. The switching circuit of the semiconductor apparatus according to claim 15, wherein the blocking section comprises:
a first selection part configured to be turned on according to the level of the first enable signal; and
a second selection part configured to be turned on according to the level of the highest voltage bias level through the first node, which is also formed at an input terminal of the first selection part.

17. The switching circuit of the semiconductor apparatus according to claim 16, wherein the first output section is configured to be activated when the first enable signal of high level is inputted so as to increase the amount of current flowing through the first node.

18. The switching circuit of the semiconductor apparatus according to claim 17, wherein the first selection part is configured to output a signal having a value of the first node to the second selection part when the enable signal has a low level.

19. The switching circuit of the semiconductor apparatus according to claim 18, wherein the second selection part is configured to output the signal outputted from the first selection part as the global bias signal according to the signal level detected at the first node.
